(19) United States
(12) Patent Application Publication
(10) Pub. No.: US 2018/0151461 A1
(43) Pub. Date: May 31, 2018

(54) STIFFENER FOR FAN-OUT WAFER LEVEL PACKAGING AND METHOD OF MANUFACTURING

(71) Applicant: GLOBALFOUNDRIES INC., Grand Cayman, KY (US)

(72) Inventor: Jae K. Cho, Niskayuna, NY (US)

(21) Appl. No.: 15/363,267

(22) Filed: Nov. 29, 2016

(51) Int. Cl. H01L 23/18; H01L 23/498; H01L 23/31; H01L 21/48; H01L 21/56; H01L 21/54

(52) U.S. Cl. CPC H01L 23/18; H01L 23/49822; H01L 23/49816; H01L 21/54; H01L 21/4857; H01L 21/4853; H01L 21/565; H01L 23/3114

(57) ABSTRACT

Aspects of the present disclosure include a wafer level chip package and method of manufacture. The wafer level chip package includes one or more semiconductor dies. A stiffener wall surrounds the one or more semiconductor dies. The stiffener wall extends from an active side to an inactive side of the semiconductor dies. There is a compliant layer encasing the one or more semiconductor dies and the stiffener wall. There is a redistribution layer disposed on the active side of the one or more semiconductor dies. The redistribution layer includes a plurality of interconnects extending to a plurality of ball pads on a surface of the redistribution layer. A plurality of solder balls is electrically connected to the plurality of ball pads.

### FIELD OF THE INVENTION

The present application relates generally to semiconductor chip packaging and more particularly to wafer level packaging of semiconductor chips.

### BACKGROUND

Fan-out Wafer Level Packaging (FO-WLP) is a cost effective option with smaller footprint to meet market demand. However, as more components are placed into a system in package configuration for shorter routing, better thermal dissipation, and faster electrical performance a larger package footprint results. Many different components reside in a single molding structure introducing thermomechanical strain/stress in ball grid array (BGA) joints resulting a packaging reliability concern

The encapsulation of the semiconductor die includes using a substrate on which the die is set facedown and allowing the molding compound to flow around and over the die without coating the active surface. In the resulting semiconductor package, the molding material is thinner over the semiconductor die than the surrounding area. Thus, delamination can occur between the semiconductor die and encapsulating material as a result of the difference between the coefficients of thermal expansion (CTE) of the molding material and the semiconductor die. In addition, warpage during package assembly can occur due to different CTEs of the components.

Moreover, a mismatch of coefficients of thermal expansions (CTEs) can damage the area where the solder bumps connect to the interconnect build-up layer. As the CTE for the die may be substantially different from the CTE of the carrier, this dissimilar rate of expansion causes thermo-mechanical stress on the solder bumps. If the stress is sufficiently large, it may damage the physical connection provided by solder bumps and as a result electrical connectivity may be lost.

Accordingly, there is a need for new chip packaging techniques.

### BRIEF SUMMARY

A first embodiment of the present disclosure provides a method for forming a semiconductor device. The method includes providing a substrate and positioning one or more semiconductor dies on a surface of the substrate. The method includes forming a stiffener wall the surface of the substrate wherein the stiffener wall surrounds the one or more semiconductor dies. The method includes forming a compliant material over the one or more semiconductor dies and stiffener wall. The substrate is removed and a redistribution layer is formed on an active side of the one or more semiconductor dies. The redistribution layer includes a plurality of interconnects extending from the active side of the one or more semiconductor dies to a plurality of ball pads on a surface of the redistribution layer. A plurality of solder balls is formed on the ball pads.

A second embodiment of the present disclosure provides wafer level chip package that includes one or more semiconductor dies, each of the one or more semiconductor dies having an inactive side and an active side. A stiffener wall surrounds the one or more semiconductor dies. The stiffener wall extends from the active side to the inactive side. The wafer level chip package includes a compliant layer encasing the one or more semiconductor dies and the stiffener wall. The compliant layer extends from the active side to the inactive side. The wafer level package includes a redistribution layer disposed on the active side of the one or more semiconductor dies. The redistribution layer includes a plurality of interconnects extending from the active side of the one or more semiconductor dies to a plurality of ball pads on a surface of the redistribution layer. A plurality of solder balls is electrically connected to the plurality of ball pads.

A third embodiment of the present disclosure provides a wafer level chip package including aa plurality semiconductor dies, each of the one or more semiconductor dies having an inactive side and an active side. The wafer level chip package includes a stiffener wall encased in a metal frame. The stiffener wall has a plurality of open regions, the open regions surrounding the plurality of semiconductor dies. The stiffener wall extends from the active side to the inactive side. The wafer level chip package includes a compliant layer encasing the plurality of semiconductor dies and the stiffener wall. The compliant layer extends from the active side to the inactive side. The wafer level chip package includes a redistribution layer (RDL) disposed on the active side or the plurality of semiconductor dies. The redistribution layer includes a plurality of interconnects extending from the active side of the plurality of semiconductor dies to a plurality of ball pads on a surface of the redistribution layer. The wafer level chip package includes a plurality of solder balls electrically connected to the plurality of ball pads.

### BRIEF DESCRIPTION OF THE DRAWINGS

These and other features of this disclosure will be more readily understood from the following detailed description of the various aspects of the invention taken in conjunction with the accompanying drawings that depict various embodiments of the disclosure, in which:

FIG. 1 illustrates a prior embodiment of a fan-out wafer level package (FO-WLP).

FIG. 2 illustrates a sectional top view of the fan-out wafer level package (FO-WLP) of FIG. 1.

FIG. 3 illustrates an embodiment of a fan-out wafer level package (FO-WLP) disclosed herein.

FIG. 4 illustrates a sectional top view of the fan-out wafer level package (FO-WLP) of FIG. 3.

FIG. 5 (a)-(f) illustrate a method of manufacturing the FO-WLP disclosed herein.

FIG. 7 illustrates an embodiment of a stiffener wall having a metal frame.

FIG. 8 illustrates an embodiment for placing a stiffener wall on a substrate.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The disclosure will now be described by reference to the accompanying figures. In the figures, various aspects of the structures have been shown and schematically represented in a simplified manner to more clearly describe and illustrate the disclosure. For example, the figures are not intended to be drawn to scale. In addition, the vertical cross-sections of the various aspects of the structures are illustrated as being rectangular in shape. Those skilled in the art will appreciate; however, that with practical structures these aspects will most likely incorporate more tapered features. Moreover, the disclosure is not limited to constructions of any particular shape.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As employed in this specification, the terms “coupled” and/or “electrically coupled” are not meant to mean that the elements must be directly coupled together; intervening elements may be provided between the “coupled” or “electrically coupled” elements.

Semiconductor devices containing semiconductor dies (also referred to semiconductor chips) are described below. The semiconductor dies may be of different types, may be manufactured by different technologies and may include for example, integrated electrical, electro-optical or electro-mechanical circuits and/or passive devices. The semiconductor dies may, for example, be designed as logic integrated circuits, analog integrated circuits, mixed signal integrated circuits, power integrated circuits, memory circuits or integrated passive devices. They may include control circuits, microprocessors or microelectromechanical components. Further, they may be configured as power semiconductor chips, such as power MOSFETs (Metal Oxide Semiconductor Field Effect Transistors), IGBTs (Insulated Gate Bipolar Transistors), JFETs (Junction Gate Field Effect Transistors), power bipolar transistors or power diodes. In particular, semiconductor dies having a vertical structure may be involved, that is to say that the semiconductor dies may be fabricated in such a way that electric currents can flow in a direction perpendicular to the main faces of the semiconductor dies. Furthermore, the devices described below may include integrated circuits to control the integrated circuits of other semiconductor dies, for example, the integrated circuits of power semiconductor chips. The semiconductor dies need not be manufactured from specific semiconductor material, for example, Si, SiC, SiGe, GaAs, AlGaAs and, furthermore, may contain inorganic and/or organic materials that are not semiconductors, such as, for example, insulators, plastics or metals.

In a fan-out type package at least some of the external contact pads and/or conductor tracks connecting the semiconductor die or chip to the external contact pads are located laterally outside of the outline of the semiconductor die or at least intersect the outline of the semiconductor die. Thus, in fan-out type packages, a peripherally outer part of the package of the semiconductor die is typically (additionally) used for electrically bonding the package to external applications, such as, e.g., application boards or, in stacked package applications, another package. This outer part of the package encompassing the semiconductor die effectively enlarges the contact area of the package in relation to the footprint of the semiconductor die, thus leading to relaxed constraints in view of package pad size and pitch with regard to later processing, e.g., second level assembly.

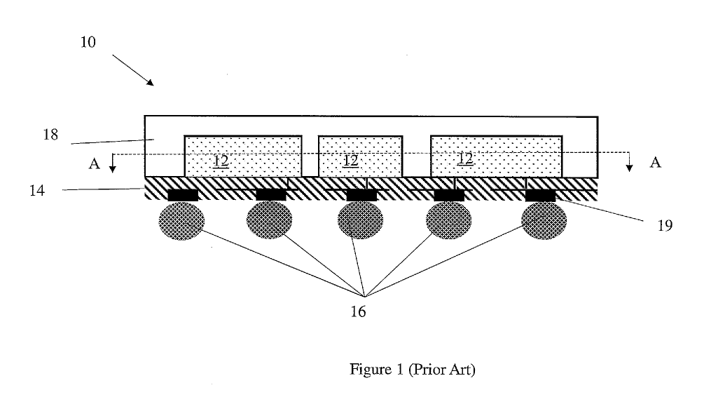

Shown in FIG. 1 is a fan-out wafer level chip package (FO-WLP) 10 of the prior art. FO-WLP 10 includes one or more semiconductor dies 12, encapsulated in a compliant material 18. On the active side of the semiconductor dies 12 is a redistribution layer 14 having interconnects 19 or conductive traces which electrically couple the semiconductor dies 12 with the contact pads 17. Solder bumps or solder balls 16 electrically coupled to the contact pads 17.

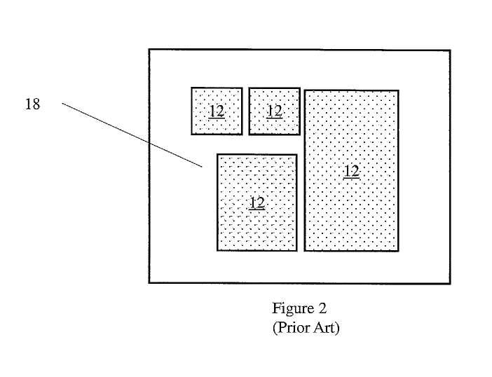

FIG. 2 shows a cross-sectional view along line A-A of FO-WLP of FIG. 1 showing the semiconductor dies 12 encapsulated in the compliant material 18.

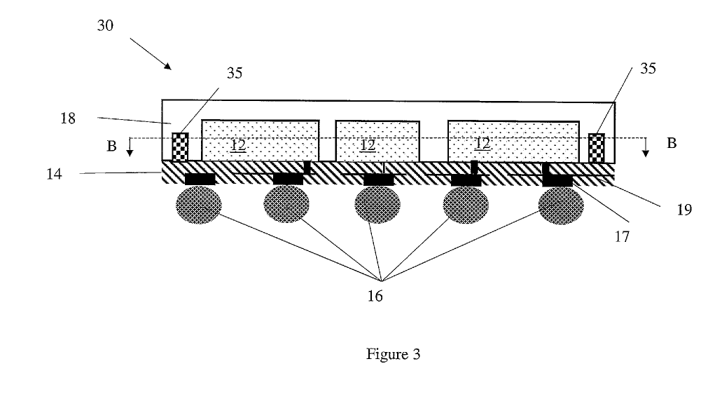

FIG. 3 shows an embodiment of a fan-out wafer level chip package 30 disclosed herein. Semiconductor dies 12 are surrounded by a stiffener wall 35 or stiffener ring. Stiffener wall 35 is made of a material having a high modulus. The modulus of stiffener wall 35 is from about 60 GPa to about 200 GPa. Stiffener wall has a coefficient of thermal expansion of less than about 20 ppm/K.

Stiffener wall 35 is selected from a material including glass fiber, copper based alloys and nickel-iron alloys. Glass fiber has a CTE of from about 2 ppm/K to about 6 ppm/K and a modulus of from about 60 GPa to about 90 GPa, Copper based alloys have a CTE of from about 5 ppm/K to about 17 ppm/K and a modulus of from about 100 GPa to about 150 GPa, Nickel-iron alloys have a CTE of from about 4 ppm/K to about 18 ppm/K and a modulus of from about 100 GPa to about 130 GPa,

Stiffener wall 35 is embedded within compliant material 18 which may be electrically insulating. Stiffener wall 35 and compliant material 18 provide structural support to the fan-out wafer level chip package 30, resulting in enhanced resistance to warpage between the different components. Stiffener wall 35 improves planarity in the final FO-WLP and additionally provides precise solder interconnect joints. Stiffener wall 35 provides better reliability performance on both component and board level. FIG. 3 shows redistribution layer 14 (RDL) that includes interconnects 19 electrically coupled to contact pads 17. The contact pads 17 are electrically coupled to solder balls 16.

The modulus of compliant material 18 is from about 5 GPa to about 100 GPa. Compliant material 18 has a coefficient of thermal expansion of less than 30 ppm/K. Compliant material 18 may be a dielectric material and may be made of any appropriate duroplastic, thermoplastic or thermosetting material such as polymeric resins, epoxies and silicones. The compliant material 18 may contain filler materials. After its deposition, the compliant material 18 may be only partially hardened and may be completely hardened after application of energy (e.g., heat, UV light, etc.).

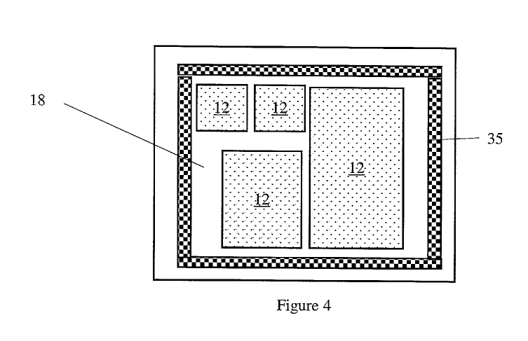

FIG. 4 shows a cross-sectional view along line B-B of FO-WLP of FIG. 3 showing the semiconductor dies 12 surrounded by stiffener wall 35 encapsulated in the compliant material 18.

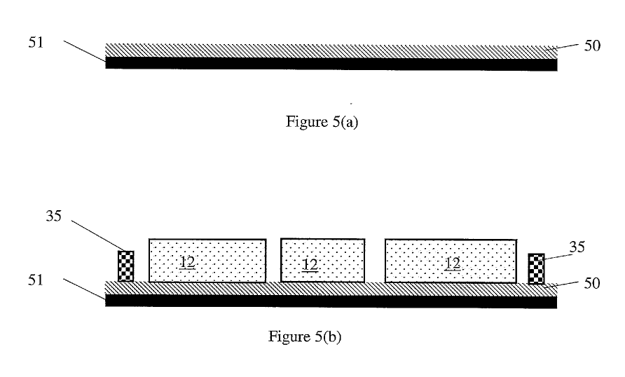

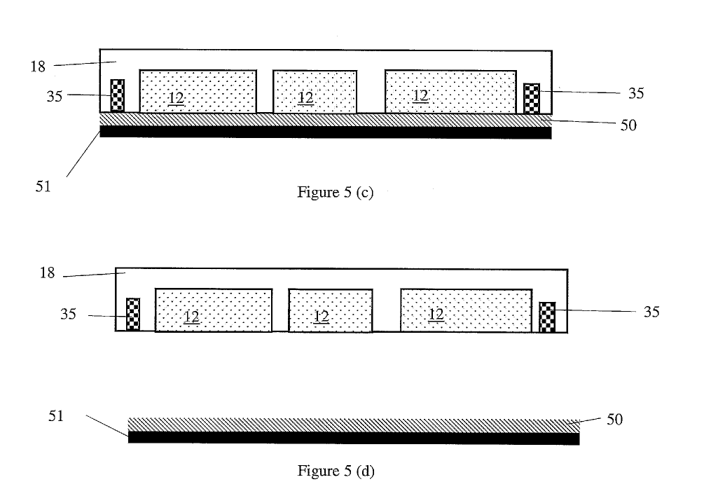

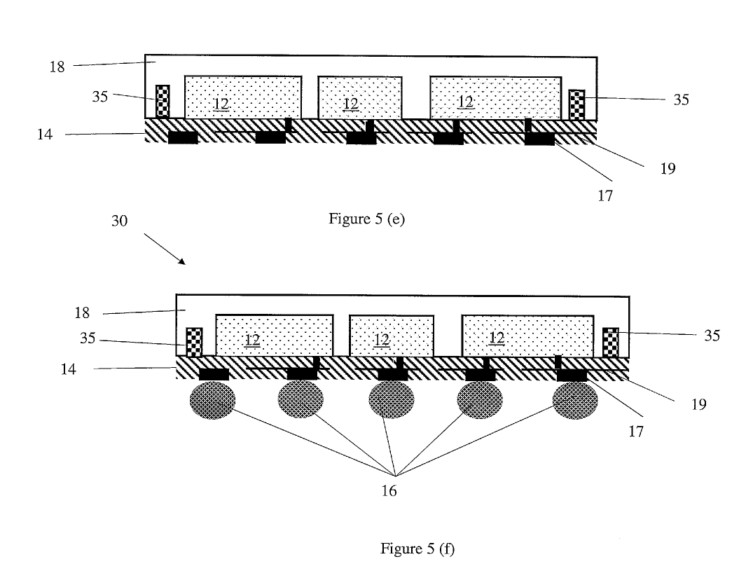

FIGS. 5(a)-(f) show and describe a process for manufacture of an embodiment described herein. In FIG. 5 (a), a substrate 51 having double sided adhesive tape 50 laminated to the surface of the substrate is shown. The substrate can be a metal or inorganic compound such as stainless steel, aluminum or glass. Semiconductor dies 12 are fixed on the adhesive tape 50 in FIG. 5(b). Alternatively, a glue material or any other adhesive material or mechanical securing means (such as a clamping device or a vacuum generator) may be associated with the substrate 51 and used for fixing the semiconductor dies 12. Semiconductor dies 12 may be arranged in an array, wherein the spacing between neighboring semiconductor dies 12 may be determined according to the desired footprint area of the semiconductor device to be fabricated. The spacing between neighboring semiconductor dies 12 may, e.g., be in the range between 0.25 mm and 10 mm. After application of semiconductor dies 12 and the substrate 51 and adhesive tape 50, stiffener wall 35 is applied to the substrate 51 and adhesive tape 50. Stiffener wall 35 completely surrounds one or more semiconductor dies 12.

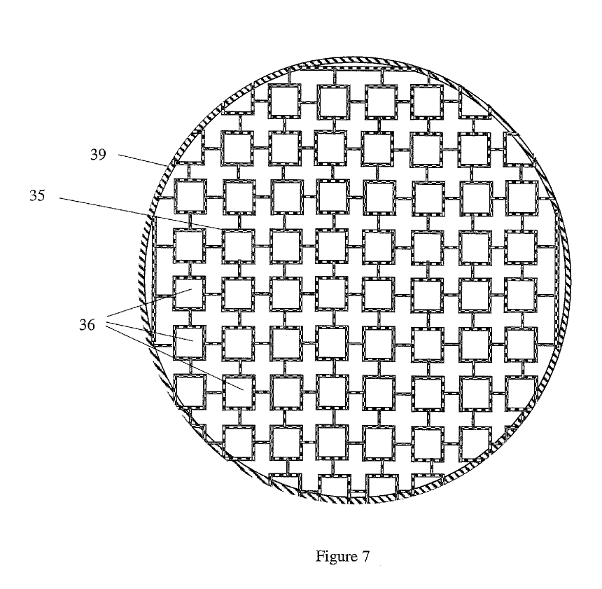

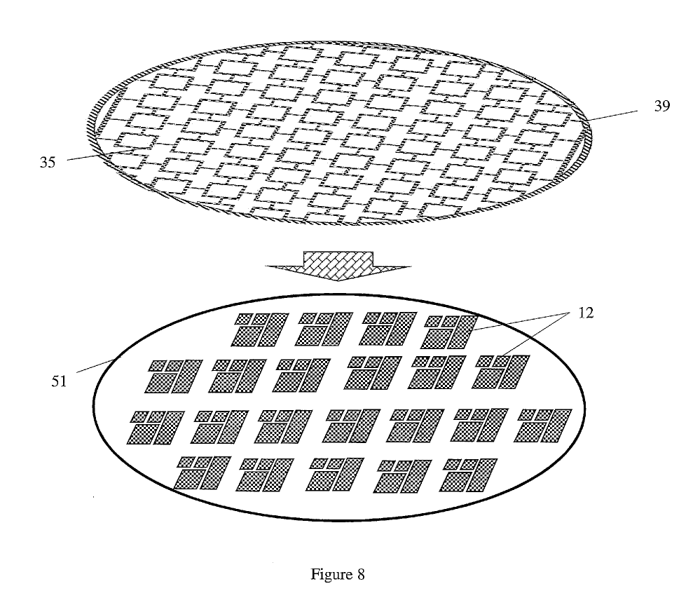

At this stage, stiffener wall 35 can be applied to the substrate 51. In an embodiment, the stiffener wall 35 is shown in FIG. 7. FIG. 7 shows a stiffener wall 35 having a plurality of open regions 36. These open regions 36 are larger than a semiconductor die(s) 12. In FIG. 8, the stiffener wall 35 is placed over a substrate 51 having a plurality of semiconductor dies 12. The openings surround one or more of the semiconductor dies 12. The stiffener wall 35 does not contact any of the semiconductor dies 12 after placement on the substrate 51. The stiffener wall 35 in FIG. 7 is encased a metal frame 39 that allows placement of the stiffener wall on a substrate through surface mount technology (SMT) by a pick and place machine. Pick-and-place machines or P&Ps, are robotic machines which are used to place surface-mount devices (SMDs) onto a substrate such as a printed circuit boards (PCB).

In FIG. 5 (c), a compliant material 18 is applied over the semiconductor dies 12 and stiffener wall 35. The molding material 18 may be applied during wafer level processing, that is during front end processing. By way of example, the compliant material 18 may be applied by a molding process within a mold chassis. Molding processes includes compression molding, injection molding, powder molding, liquid molding, dispensing or laminating. Compliant material 18 may be made of any appropriate duroplastic, thermoplastic or thermosetting material such as polymeric resins, epoxies and silicones. The compliant material improves the CTE mismatch between components on the semiconductor device 30 to decrease stress and warpage of the FO-WLP.

After applying the compliant material 18, the substrate 51 including the adhesive tape 50 is debonded from the semiconductor dies 12, compliant material 18 and stiffener wall 35. This is shown in FIG. 5(d).

In FIG. 5 (e), a redistribution layer 14 including one or more interconnects 19 or conductive traces that electrically couple an active surface of the semiconductor dies 12 to contact pads 17, is applied to the wafer package of FIG. 5(d).

The redistribution layer 14 having the one or more interconnects 19 may generated through depositing photoresist, forming openings in the photoresist and plating or deposition of the interconnects 19 and pads 17 as is known in the art.

Solder balls 16 may be attached to the contact pads 17 as illustrated in FIG. 5(f). The solder balls 16 or solder deposits may be applied to the contact pads 17 by so-called “ball placement”, in which pre-shaped balls composed of solder material are applied to the contact pads 17. As an alternative to “ball placement”, the solder balls 16 may, for example, be applied by means of stencil printing with a solder paste, followed by a heat-treatment process. The solder material may be formed from metal alloys which are composed, for example, from the following materials: SnPb, SnAg, SnAgCu, SnAgCuNi, SnAu, SnCu and SnBi. The solder balls 16 may be used to electrically couple the semiconductor dies 12 to other components. The solder balls 16 are electrically coupled to the semiconductor dies via the interconnects 19 and contact pads 17.

The semiconductor dies 12 may have been manufactured on the same semiconductor wafer, but may alternatively have been manufactured on different semiconductor wafers. Furthermore, the semiconductor dies 12 may be physically identical, but may also contain different integrated circuits and/or represent other components.

The contact pads 17 may represent the external terminals of the semiconductor package. They may be accessible from outside the package and may thus allow electrical contact to be made with the semiconductor chip(s) from outside the package. Furthermore, the contact pads 17 may be thermally conductive and may serve as heat sinks for dissipating the heat generated by the semiconductor chip or chips embedded in the semiconductor package. The contact pads 17 may be composed of any desired electrically conductive material, for example, of a metal, such as copper, aluminum or gold, a metal alloy or an electrically conductive organic material.

The interconnects 19 may be wiring layers to make electrical contact with the semiconductor dies 12 from outside the package and/or to make electrical contact with other semiconductor dies 12 and/or components contained in the package. Interconnects 19 may be manufactured with any desired geometric shape and any desired material composition. Interconnects 19 may, for example, be composed of conductor tracks, but may also be in the form of a layer covering an area. They may be used to electrical couple the contact pads 17 of the package. Any desired metal, for example, aluminum, nickel, palladium, silver, tin, gold or copper, or metal alloys may be used as the material.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

1-9. (canceled)

10. A wafer level chip package comprising:
one or more semiconductor dies, each of the one or more semiconductor dies having an inactive side and an active side;
a stiffener wall surrounding the one or more semiconductor dies, the stiffener wall extending from the active side to the inactive side;
a compliant layer encasing the one or more semiconductor dies and the stiffener wall, the compliant layer extending from the active side to the inactive side;
a redistribution layer (RDL) disposed on the active side or the one or more semiconductor dies, the redistribution layer including a plurality of interconnects extending from the active side of the one or more semiconductor dies to a plurality of ball pads on a surface of the redistribution layer; and
a plurality of solder balls electrically connected to the plurality of ball pads.

11. The wafer level chip package of claim 10, wherein the stiffener wall comprises a material having a modulus of from about 60 GPa to about 200 Pa.

12. The wafer level chip package of claim 10, wherein the stiffener wall comprises a material having a coefficient of thermal expansion of less than 20 ppm/K.

13. The wafer level chip package of claim 10, wherein the stiffener wall comprises a material selected from the group consisting of glass fibers, copper-based alloys and nickel iron alloys.

14. The wafer level chip package of claim 10, wherein the compliant layer comprises a material selected from the group consisting of: selected from the group consisting of: polymeric resins; epoxies and silicones.

15. The wafer level chip package of claim 10, wherein the stiffener wall includes a metal frame.

16. A wafer level chip package comprising:
a plurality of semiconductor dies, each of the one or more semiconductor dies having an inactive side and an active side;
a stiffener wall encased in a metal frame, the stiffener wall having a plurality of open regions, the open regions surrounding the plurality of semiconductor dies, the stiffener wall extending from the active side to the inactive side;
a compliant layer encasing the plurality of semiconductor dies and the stiffener wall, the compliant layer extending from the active side to the inactive side;
a redistribution layer (RDL) disposed on the active side or the plurality of semiconductor dies, the redistribution layer including a plurality of interconnects extending from the active side of the plurality semiconductor dies to a plurality of ball pads on a surface of the redistribution layer; and
a plurality of solder balls electrically connected to the plurality of ball pads.

17. The wafer level chip package of claim 16, wherein the stiffener wall comprises a material having a modulus of from about 60 GPa to about 200 Pa.

18. The wafer level chip package of claim 16, wherein the stiffener wall comprises a material having a coefficient of thermal expansion of less than 20 ppm/K.

19. The wafer level chip package of claim 16, wherein the stiffener wall comprises a material selected from the group consisting of glass fibers, copper-based alloys and nickel iron alloys.

20. The wafer level chip package of claim 16, wherein the compliant layer comprises a material selected from the group consisting of: selected from the group consisting of: polymeric resins; epoxies and silicones.
